(19) United States
(12) Patent Application Publication
(10) Pub. No.: US 2004/0021506 A1
(43) Pub. Date: Feb. 5, 2004

(54) Technique and circuit for fast settling of noise reduction filters used in voltage references

(76) Inventor: Gabriel E. Tanase, Cupertino, CA (US)

Correspondence Address: PERKINS COIE LLP, P.O. BOX 2168, MENLO PARK, CA, 94026, US

(21) Appl. No.: 10/209,330

(22) Filed: Jul. 30, 2002

(51) Int. Cl. H03B 1/00

(52) U.S. Cl. 327/552

(57) ABSTRACT

The present invention provides a method and apparatus to significantly improve the settling times of noise reduction filters in voltage reference circuits. Resistor-capacitor (RC) filter networks used as noise reduction filters in the present invention are provided switches, controlled through a logic pulse signal, which places the filter network into an alternate operation mode. This alternate operation mode periodically closes parallel switches allowing the filter network to pre-charge RC filter capacitors to a steady-state value at power-up, or during any other transient condition, at greater speeds by bypassing selected resistors within the RC filter network.

### CROSS REFERENCE TO RELATED APPLICATIONS

Not applicable.

### STATEMENT REGARDING FEDERALLY SPONSORED RESEARCH

Not applicable.

### BACKGROUND OF INVENTION

1. Field of Invention

The present invention is related to the manufacture and use of resistance-capacitance (RC) filters in reducing wide-band noise of voltage reference circuits. Output voltage settling times associated with traditional RC filters are significantly improved through selectively switching filter capacitors, such that steady state charges are reached much more quickly.

2. Description of Related Art

The reduction, elimination or control of noise in electronic systems is typically a primary concern in design parameters. Noise, which is present in practically every electronic system, tends to limit signal precision and detectability in electronic systems. Detrimental electronic noise may be due to several sources and may be classified as one of several types, such as thermal (Johnson) noise, shot noise or flicker noise.

Thermal or Johnson noise is a function of temperature and is due to the random motion of electrons due to thermal agitation. Thermal noise is considered “white noise” since the rms value remains constant for all frequencies. Flicker noise however, is a function of frequency. Due to surface imperfections, electron conductance creates random current fluctuations, which increase at lower frequencies. In any case, the result is voltages or currents which accompany and tend to contaminate the desired signal.

Solutions to electronic system noise have included the proper grounding of components in which undesired noise is subject to generation, as well as proper shielding of components. However this may only address some of the noise created. To increase the precision of certain electronic systems, greater measures need to be taken. To accomplish this, the characteristics and effects of electronic noise should be taken into account, and system operational solutions considered.

Consider the effects of voltage noise on binary digital circuits. To correctly interpret input signals as high or low, a certain tolerance to voltage noise capacitively or inductively coupled into the circuit is required. Component manufacturers are forced to design high and low noise margins for worse case scenarios. Furthermore, digital circuit design may be used to reject injected noise, however analog circuits, even properly designed, will propagate this noise.

An efficient way to reduce output voltage noise, a critical parameter for voltage references, is the use of “on-chip” filters. Such on-chip filters do not require external noise reduction capacitors and, if properly designed, occupy reasonable space on the chip. In addition, the output noise voltage is reduced without incurring any quiescent current increase penalties. However, on-chip filters create prohibitively long settling time of the output voltage. As widely known in the art, low-pass filters contain capacitors wherein the time-constant associated with these capacitors is related to the roll-off frequency of the filter. Lower corner frequencies mean longer time-constants and longer settling time of the filter. The transient response of resistor-capacitor networks defines the time required to charge the capacitor(s) to their steady-state values. For instance, a circuit as shown in Prior Art FIG. 1 charges capacitor 10 to a steady-state value,

v_{C}=V_{DC}

based upon,

v_{C}=V_{DC}−V_{DC}e^{-t/RC}

where v_{C} is the capacitor charge value and V_{DC} is the applied charging voltage.

This transient response creates the undesirable settling time for these on-chip filters. Therefore what is needed is a noise reduction RC filter with significantly improved settling times.

### BRIEF SUMMARY OF THE INVENTION

The present invention provides a method and apparatus to significantly improve the settling times of noise reduction RC filters in voltage reference circuits. Traditional RC filter networks used as low-pass noise reduction filters in the present invention are provided a “charge-up” logic pulse signal which places the filter network into an alternate operation mode. This alternate operation mode allows the filter network to pre-charge filter capacitors to a steady-state value at power-up or during any other transient condition.

The charge-up logic pulse is created by a charge-up signal generator and may be used to control a series of switches positioned in the RC filter network. During transient conditions, the logic pulse is used to direct the closure of switches for a duration providing rapid charging of the filter network capacitors.

### BRIEF DESCRIPTION OF DRAWINGS

These and other objects, features and characteristics of the present invention will become more apparent to those skilled in the art from a study of the following detailed description in conjunction with the appended claims and drawings, all of which form a part of this specification. In the drawings:

FIG. 1 illustrates a PRIOR ART RC network;

FIG. 2 illustrates a block diagram of one embodiment of the present invention in use with one embodiment of a filter network;

FIG. 3A illustrate schematics of one embodiment of the present invention coupled to a prior art voltage reference core;

FIG. 3B illustrate schematics of another embodiment of the present invention coupled to a prior art voltage reference core; and

FIG. 4 illustrates a schematic of yet another embodiment of the present invention coupled to a prior art output amplifier.

### DETAILED DESCRIPTION OF PRESENTLY PREFERRED EXEMPLARY EMBODIMENTS

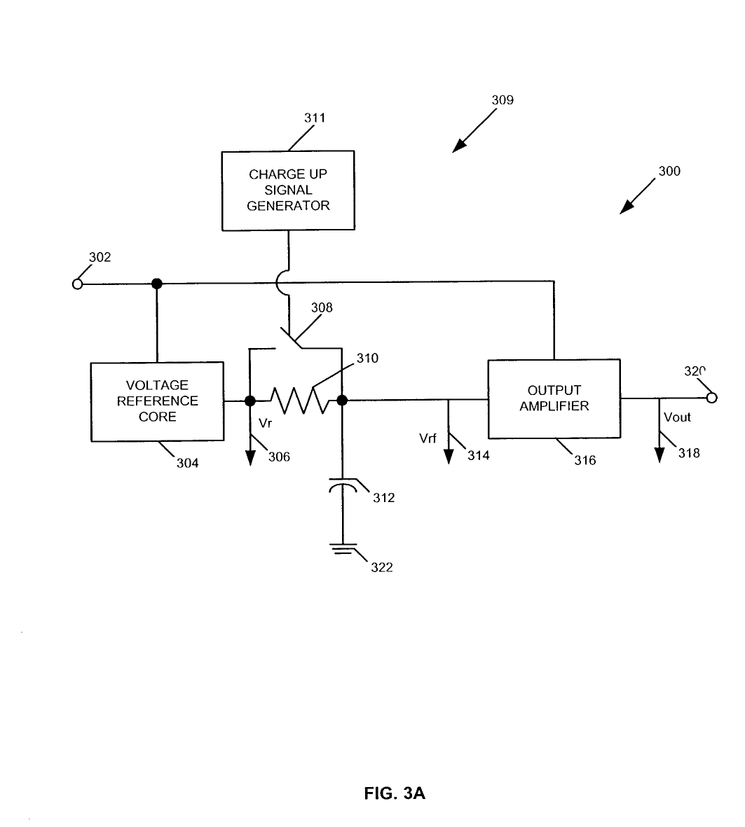

An object of the present invention is the reduction in settling time associated with traditional noise reduction filters used in voltage reference circuits. FIG. 2 illustrates a filter system, such as an RC or RLC filter network, comprised in part of “n” capacitors and ordinary operation of this filter system would include the transient response of the RC networks within the filter system. As stated earlier, application of a voltage V_{DC} to the RC network results in a capacitor charge response defined by,

v_{C}=V_{DC}−V_{DC}e^{-t/RC}

where v_{C} is the capacitor voltage, and steady-state is achieved at,

v_{C}=V_{DC}

In FIG. 2 however, at power-up or any other transient condition, the charge-up signal generator 11 produces a logic pulse signal 13 (CH-UP), which changes the filter system 12 operation, such that capacitors C1, C2, . . . Cn 14 will rapidly charge reaching steady-state values. The width of pulse 13 determines the duration of rapid charge therefore pulse width must be sufficient to allow all capacitors at 14 to reach steady-state values.

During the CH-UP pulse duration, filter system 12 operates in a first mode, generating steady-state voltages Vtr1, Vtr2, . . . , Vtrn, across capacitors C1, C2, . . . Cn respectively. The signal pulse width is sufficient to allow all capacitors to reach steady-state values. Once charged, the signal switches the filter system to a second mode of operation, a normal operation configuration. In this case, the steady-state voltages across capacitors 14 will have been charged to V1, V2, . . . Vn voltage values. Therefore once returned to a normal operation configuration, a significantly improved settling time for the filter results since the earlier charging of the capacitors has resulted in V1=Vtr1, V2=Vtr2, . . . Vn=Vtrn.

The present invention provides a charge up signal generator 11, creating a logic pulse signal 13, which when electrically coupled to a noise reduction filter system 12, may be used to control the operation of the filter system. The CH-UP pulse or logic pulse signal 13 may control a plurality of discrete or integrated switches that transform a first circuit configuration corresponding to the first operational mode, in response to the logic pulse signal to a second circuit configuration corresponding to a second operational mode. At power up or during any other transient condition, a first mode of operation allows the filter system to rapidly charge RC filter network capacitors 14 of the filter system 12 to steady-state values. The duration of the logic pulse signal provided by the charge up signal generator corresponds to the time required for filter system capacitors to reach steady-state voltage values. Once charged, the filter network is returned to a second mode or normal operation.

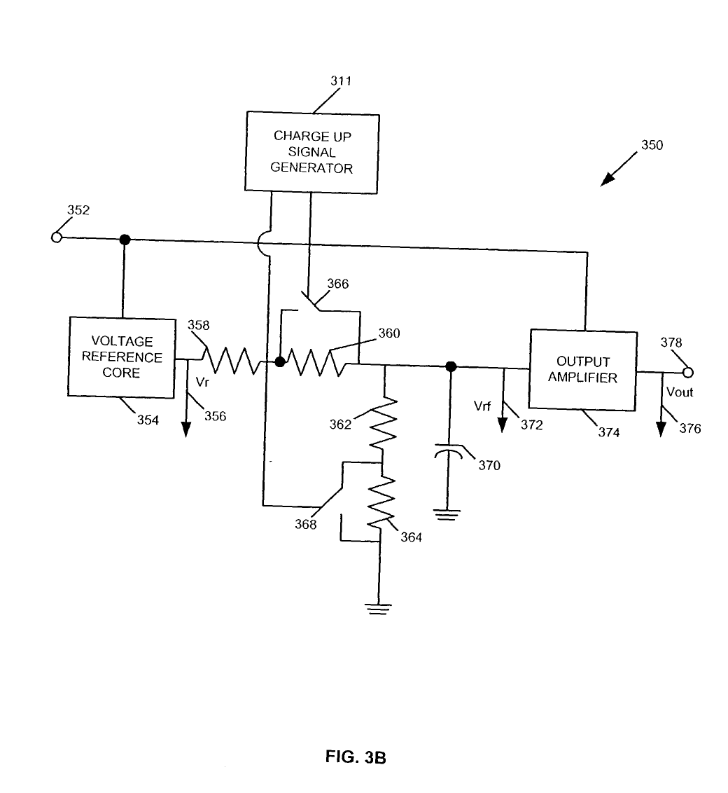

In FIG. 2, a block diagram of one embodiment of the present invention is shown in circuit 200. The filter system 12 may consist of RC or RLC filter networks arranged to operate in first and second modes, with the associated capacitors shown at 14, or alternatively with associated inductors (not shown here). The charge-up signal generator is shown at 11 and provides the logic pulse signal 13 electrically coupled to the filter system. The block diagram of FIG. 2 may be implemented in several ways as shown in FIG. 3A and 3B.

FIG. 3A contains a voltage reference core 304 electrically coupled to an output amplifier 316 via an improved RC filter network 309. The filter network is 309 comprised of a first resistor 310, first capacitor 312, switch 308 is electrically coupled in parallel with the first resistor 310, and a charge up signal generator 11 controlling operation of the switch 308. The voltage reference core 304 and the output amplifier 316 each have an input electrically coupled to an input voltage 302. The reference voltage 306 developed by the voltage reference core 304 is electrically coupled to the output amplifier 316 via a first resistor 310 and a switch 308. A first capacitor 312 electrically couples the signal to ground and the output amplifier 316 produces an output voltage 318 at output 320.

The RC filter network 309 shown coupling the output amplifier to the voltage reference core reduces the wide-band noise of the voltage reference core 304. As widely known to those skilled in the art, the RC filter 309 is an effective method to reject certain signal components while allowing other signals to pass, often referred to as low-pass, high-pass and band-pass filters. An alternative to the RC filter 309, is the inductor-capacitor (LC) filter however, the RC filter network 309 is considered superior to the LC filter network due to the difficulties of inductor fabrication and use on integrated circuits. In the present invention, an RC filter network 309 between components can be integrated on the same silicon-chip with the voltage reference core 304. However, it should be apparent to one skilled in the art that the innovative concepts of the present invention are equally applicable to a discrete filter system.

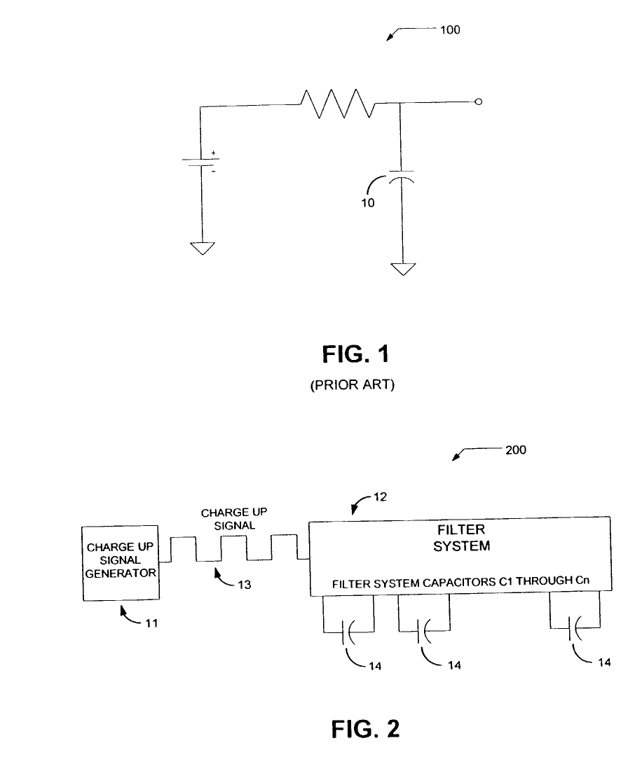

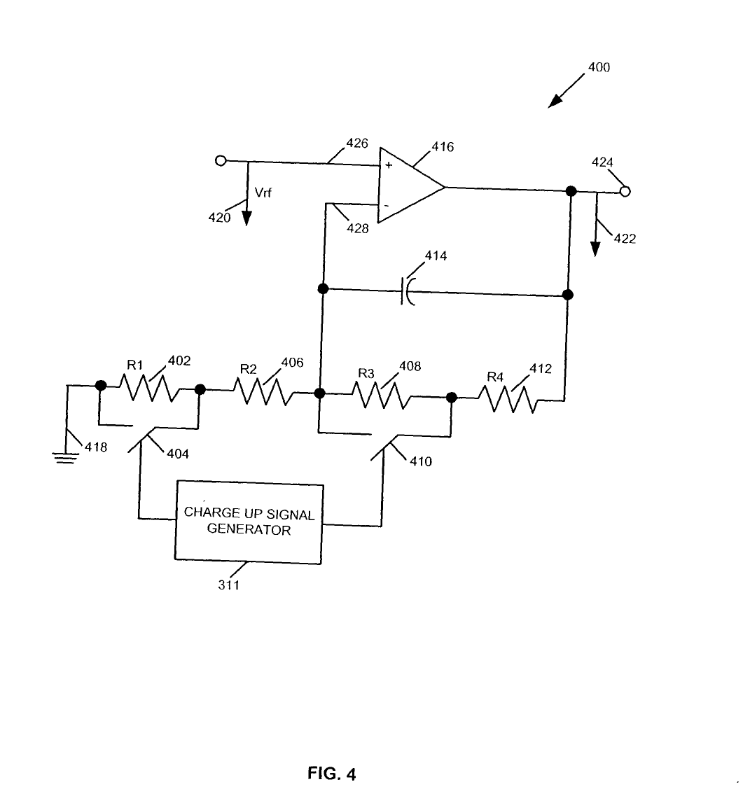

Prior art RC filter networks have significant drawbacks in use. One such drawback the present invention addresses is the large time-constant values RC filter networks exhibit. Time-constant values in the order of 10 ms or more are common, resulting in an internal voltage 314 (Vrf) and output voltage 318 (Vout) suffering large delays at power-up. However in the present invention shown in FIG. 3A, an analog switch 308 is electrically coupled in parallel with resistor 310. At power-up, switch 308 is switched ON (closed) for a short time by the charge up signal generator 11 (see FIG. 2), enabling the first capacitor 312 to charge up and reach steady-state voltage much more quickly than charging through the first resistor 310. The design and operation of signal generators such as the one described herein will be readily apparent to those skilled in the art. The duration of a pulse 13 (see FIG. 2) provided by the signal generator is used to control the period during which the switch is ON and charging capacitor 312 bypassing resistor 310. Once charged, the logic pulse signal switches off switch 308 (switch is open) allowing the normal operation of the RC filter network 309. By having a switch in parallel with the resistor 310, the current bypasses the resistor 310 and the capacitor 312 is charged at a much faster rate. It should be apparent to one skilled in the art that the functions of a switch may be performed by either a discrete switch, a simple integrated switch such as an integrated transistor, or a more complex switching system depending on the requirements of the particular system. Furthermore, the teachings of the present invention should not be construed as limited to bypassing a single resistor such as shown in FIG. 1. Alternative embodiments may be envisaged that would include more complex passive or active networks, wherein the control signal 13 may trigger a transition from the initial operational mode to a second steady state mode through a more complex mode transition system. Examples of more complex system implementations according to the teachings of the present invention are discussed below in FIG. 3B and FIG. 4.

From our earlier equation of FIG. 1, application of a voltage V_{DC} to the network results in a capacitor charge response defined by,

v_{C}=V_{DC}−V_{DC}e^{-t/RC}

where v_{C} is the capacitor voltage, and steady-state is achieved at,

v_{C}=V_{DC}

FIG. 3B shows the use of an RC noise filter/divider where an output voltage 376 is required to be lower than the reference voltage 356 developed by the voltage reference core 354. FIG. 3B contains a voltage reference core 354 electrically coupled to an output amplifier 374 via an improved RC filter network. The filter network is comprised of a first, second, third and fourth resistor 358, 360, 362 and 364, and a capacitor 370, a first switch 366 electrically coupled in parallel with the second resistor 360, a second switch 368 electrically coupled in parallel with the fourth resistor 364, and a charge up signal generator 11 for controlling the switches 366 and 368. The voltage reference core 354 and the output amplifier 374 have an input electrically coupled to an input voltage 352. The reference voltage 356 developed by the voltage reference core 354 is electrically coupled to the output amplifier 374 via the series connection of the first and second resistors 358 and 360. The second resistor is electrically coupled in parallel with switch 366 and the coupling between resistor 360 and output amplifier 374 is electrically coupled to ground via the capacitor 370. Furthermore, the coupling between resistor 360 and output amplifier 374 is electrically coupled to ground via the series connection of the third and fourth resistors 362 and 364, where the fourth resistor 364 is electrically coupled in parallel with switch 368. The output amplifier 374 then produces output voltage 376 at output 378.

The voltage divider of resistors R1 358, R2 360, R3 362 and R4 364 in FIG. 3B bring the voltage 372 (the input voltage to the output amplifier 374) to the desired dc level. Noise reduction is achieved by the filter capacitor C 370, which reduces the wide-band noise of the voltage reference. The appropriate design of the RC noise filter/divider reduces the wide-band noise significantly, however effective filtering requires large time-constant values,

τ_{f}=C×(R1+R2)∥(R3+R4)

which unacceptably increases the power up/transient regime settling time.

The present invention shown in FIG. 3B reduces the settling time without adding power consumption or degrading output noise. The voltage divider resistor values are such that,

R3/R1=(R4+R3)/(R1+R2)

(where R1<<R2, R3<<R4)

At power up, switches 366 and 368 are switched ON for a short time by charge up signal 13 (see FIG. 2), long enough to ensure proper settling of the output voltage within the required tolerance. Capacitor 370 will charge/discharge through resistors 358 and 362 with a smaller time constant,

τ_{f}=C×(R1∥R3)

When switches 366 and 368 are switched OFF, the voltage across capacitor 370 does not change if the above mentioned resistor ratio is achieved. This dual mode filter system allows for operation in a first system configuration where the capacitor 370 is charged at fast rate because of a smaller time constant associated with the first system configuration, where some of the resistors are bypassed. A second mode of operation begins after the capacitor is pre-charged and the bypass switches are opened (turned off) for normal RC filter operation. The transition from one mode to the other is controlled by the charge up signal 13 generated by the charge up signal generator 11.

Another schematic of an embodiment is shown in FIG. 4, in which the circuit architecture reduces the output voltage noise of the output amplifier in FIGS. 3A and 3B. Circuit 400 in FIG. 4 contains an output amplifier 416, first (R1), second (R2), third (R3) and fourth (R4) resistors 402, 406, 408, 412, first and second switches, 404, 410, a capacitor (C) 414 and a charge up signal generator 311. The first, second, third and fourth resistors are electrically coupled in series. The first resistor 402 is electrically coupled in parallel with the first switch 404 and electrically coupled to the second resistor 406. The second resistor 406 is electrically coupled to the third resistor 408 which is electrically coupled in parallel with the second switch 410. The third resistor 408 is electrically coupled to the output via the fourth resistor 412. The third capacitor 414 is electrically coupled in parallel to the series coupling of resistors 408 and 412.

FIG. 4 also includes an output amplifier 416 as shown in FIGS. 3A and 3B. Amplifier 416 has a positive input 426, a negative input 428, and an output 424, with various other inputs, such as supply voltage and ground included but not shown in FIG. 4. The positive input of amplifier 416 is electrically coupled to a reference voltage at 420, shown and described in FIG. 3 as the output of voltage reference core 304 via the new RC filter network. The output of amplifier 416 is electrically coupled to an output at 424. Furthermore, a feedback loop is placed between the output and negative input of amplifier 416 via the parallel coupling of the capacitor 414 and resistors 408 and 412, where resistor 408 is electrically coupled in parallel with switch 410.

In the case of very low power circuits, the gain-setting ladder comprised of resistors R1 402, R2 406, R3 408 and R4 412, has a high resistance which adds significant noise at the output 424. The new RC filter placed in the feed back loop, containing the capacitor 414, is employed to reduce this noise. Effective filtering at this point requires large time-constant values where,

τ=C3×(R1+R2)∥(R3+R4)

However, this creates unacceptable settling times at power up. The present invention reduces the settling time without adding power consumption or degrading output noise. The output ladder resistor values 402, 406, 408 and 412 are such that,

R4/R2=(R4+R3)/(R1+R2)

(where R2<<R1, R4<<R3)

At power-up, switches 404 and 410 are switched ON for a short time by the logic pulse signal (charge up signal 13) described in FIG. 2, by the charge up signal generator 11. The third capacitor 414 is charged through resistors 406 and 412 with a smaller time-constant than prior art RC filter feedback loops. When the first and second switches 404 and 410 are switched OFF, the voltage across the capacitor 414 will not change if the above mentioned resistor ratio is achieved. This is accomplished by selecting values for the resistor forming the output ladder that would satisfy the above equations.

In addition to the above mentioned examples, various other modifications and alterations of the inventive technique and circuit for fast settling noise reduction filter may be made without departing from the invention. Accordingly, the above disclosure is not to be considered as limiting and the appended claims are to be interpreted as encompassing the true spirit and the entire scope of the invention.

We claim,

1. A semiconductor device suitable for use as a fast settling noise reduction filter, wherein said semiconductor device is comprised of:
a first RC filter network, said first RC filter network having an RC filter network input, an RC filter network output, a ground and a charge up signal control port, said network having a first and second mode of operation;
a voltage reference core, said voltage reference core having a voltage reference core input and voltage reference core output, said voltage reference core input electrically coupled with a supply voltage and said voltage reference core output electrically coupled with said first RC filter network input;
an output amplifier, said output amplifier having a positive input and a negative input and an amplifier output, said positive input electrically coupled with said RC filter network input, said negative input electrically coupled with said first RC filter network output, said amplifier output being an output of said fast settling noise reduction filter; and
a charge up signal generator, said charge up signal generator having an output, wherein said generator output is electrically coupled with said first RC filter network charge up signal control port.

2. A semiconductor device as recited in claim 1 wherein said first RC filter network is comprised of a first capacitor, a first resistor, and a first bypass switch, said first resistor electrically coupled in series between said RC filter network input and output, said first capacitor electrically coupled in series between said RC filter network output and said ground, said first bypass switch electrically coupled in parallel with said first resistor, said first bypass switch controlled by said output of said charge up signal generator.

3. A semiconductor device as recited in claim 2 wherein said output of said charge up signal generator closes said first bypass switch during startup and transient conditions, said closing of said first bypass switch charging said first capacitor of said RC filter through said closed first bypass switch.

4. A semiconductor device as recited in claim 3 wherein said charging of said first capacitor through said closed first bypass switch is much more rapid than charging through said first resistor of said RC filter.

5. A semiconductor device as recited in claim 4 wherein said output of said charge up signal generator is comprised of a logic pulse signal, said logic pulse signal having an ON condition and an OFF condition, said ON condition corresponding to said first operation mode and said OFF condition corresponding to said second operation mode, wherein fast charging of said first capacitor to steady-state values occurs in said first operation mode.

6. A semiconductor device suitable for use as a fast settling noise reduction filter, wherein said semiconductor device is comprised of:
a first RC filter network, said first RC filter network having a network input, network output, first and second ground, and charge up signal control port, said network having a first and second mode of operation;
a voltage reference core, said voltage reference core having an input and an output, said input electrically coupled to an input voltage and said output electrically coupled to said first RC filter network input;
an output amplifier, said output amplifier having a positive and negative input and an output, said positive input electrically coupled to said input voltage, said negative input electrically coupled to said first RC filter network output; and
a charge up signal generator, said charge up signal generator having an output, said output electrically coupled to said first RC filter network charge up signal port.

7. A semiconductor device as recited in claim 6 wherein said first RC filter network is comprised of a first capacitor, a first, second, third and fourth resistor, and a first and second bypass switch, said first and second resistors electrically coupled in series between said RC filter input and output, said third and fourth resistors electrically coupled in series between said RC filter output and said first ground, said first bypass switch electrically coupled in parallel with said second resistor, said second bypass switch electrically coupled in parallel with said fourth resistor, said first and second bypass switch controlled by said output of said charge up signal generator.

8. A semiconductor device as recited in claim 7 wherein said first capacitor is electrically coupled between said RC filter output and said second ground.

9. A semiconductor device as recited in claim 8 wherein said output of said charge up signal generator closes said first and second bypass switch during startup and transient conditions, said closing of said first and second bypass switch charging said first capacitor of said RC filter through said closed first and second bypass switch.

10. A semiconductor device as recited in claim 9 wherein said charging of said first capacitor through said closed first and second bypass switch is much more rapid than charging through said third and fourth resistor of said RC filter.

11. A semiconductor device as recited in claim 10 wherein said output of said charge up signal generator is comprised of a logic pulse signal, said signal having an ON condition and an OFF condition, said ON condition corresponding to said first operation mode and said OFF condition corresponding to said second operation mode, wherein first capacitor is fast charged to a steady-state during said first mode.

12. A method to improve settling time for electronic circuit output signals comprising the steps of:
electrically coupling a voltage reference core circuit with an output amplifier circuit producing an output signal via a first RC filter having capacitive, resistive and bypass elements, said first RC filter capable of first and second modes of operation;
controlling said first RC filter with a logic pulse signal, said logic pulse signal placing said first RC filter in said first mode during start-up or transient conditions, said logic pulse signal placing said first RC filter in said second mode during all other conditions;
precharging said RC filter capacitive elements to steady-state values in said first mode of operation through said bypass elements; and
improving settling time of said output signal during said second mode of operation through the use of said precharged RC filter capacitive elements.

13. A method as recited in claim 12 wherein said first mode of operation is comprised of bypassing said resistive elements of said RC filter, said bypassing allowing rapid charging of capacitive elements through said bypass elements.

14. A method as recited in claim 13 wherein said duration of said first mode is controlled by said logic pulse signal, said duration allowing said capacitive elements to reach steady state value.

15. A method as recited in claim 14 wherein said logic pulse signal places said RC filter into said second mode once said capacitive elements reach said steady state.

16. A method as recited in claim 15 wherein said second mode of operation includes removing said bypass from said resistive elements of said RC filter.

17. A method as recited in claim 16 wherein said resistive elements include at least one resistor, said capacitive elements include at least one capacitor, and said bypass elements include at least one switch.

18. A system suitable for use as a fast settling noise reduction filter comprising:
a filter system for filtering noise, the filter system operative in two operational modes, wherein a first operational mode corresponds to a pre-charge mode providing for fast charging of at least one energy storage element at power up, and a second operational mode corresponding to a steady-state operation of the filter system; and
a charge up signal generator for generating a charge up signal wherein said charge up signal controls the transition between the two operational modes by switching ON and OFF a plurality of bypass switches, wherein selective resistance elements within the filter system are bypassed when the switches are turned ON, reducing a time constant associated with the filter system.

19. The system of claim 18 wherein the filter system is an RC filter system.

20. The system of claim 19 wherein the filter system includes active elements.

21. The system of claim 18 wherein the filter system is part of a voltage reference system.

22. The system of claim 18 wherein the filter is an RL filter system.

23. The system of claim 18 wherein the filter is an RLC filter system.

24. The system of claim 18 wherein the plurality of switches are discrete switches.

25. The system of claim 8 wherein the plurality of switches are integrated switches.

26. A noise reduction apparatus comprising:
An RC filter network having a charging mode and a steady state mode, said network including at least one capacitive element;
a bypass mechanism for rapidly charging said at least one capacitive element, wherein said bypass mechanism is associated with said charging mode; and
wherein said at least one capacitive element is operative to reduce noise in an output voltage during said steady state mode.

27. The apparatus of claim 26, wherein said RC filter network includes at least one resistive element, wherein said bypass mechanism is operative to bypass said at least one resistive element.

28. The apparatus of claim 27, wherein said bypass mechanism includes at least one charge up signal generator operative to close at least one electrical path, wherein said at least one electrical path is operative to substantially short said at least one resistive element.

29. The apparatus of claim 26, wherein said RC filter network is operative to receive an input voltage, said apparatus further comprising a voltage reference core for providing a reference voltage to said RC filter network, wherein said reference voltage is responsive to said input voltage.

30. The apparatus of claim 29 further including an output amplifier for producing an output voltage in response to said input voltage and said reference voltage.
